(19) United States
(12) Patent Application Publication
(10) Pub. No.: US 2005/0082526 A1
(43) Pub. Date: Apr. 21, 2005

(54) Techniques for layer transfer processing

(75) Inventors: Stephen W. Bedell, Wappingers Falls, NY (US); Keith Edward Fogel, Nanuet, NY (US); Bruce Kenneth Furman, Poughquag, NY (US); Sampath Purushothaman, Yorktown Heights, NY (US); Devendra K. Sadana, Plesantville, NY (US); Anna Wanda Topol, Wappingers Falls, NY (US)

Correspondence Address: Ryan, Mason & Lewis, LLP;Suite 205, 1300 Post Road, Fairfield, CT, 06824, US

(73) Assignee: International Business Machines Corporation, Armonk, NY (US)

(21) Appl. No.: 10/685,636

(22) Filed: Oct. 15, 2003

(51) Int. Cl. H01L 29/04

(52) U.S. Cl. 257/52

(57) ABSTRACT

Techniques for the fabrication of semiconductor devices are provided. In one aspect, a layer transfer structure is provided. The layer transfer structure comprises a carrier substrate having a porous region with a tuned porosity in combination with an implanted species defining a separation plane therein. In another aspect, a method of forming a layer transfer structure is provided. In yet another aspect, a method of forming a three dimensional integrated structure is provided.

### FIELD OF THE INVENTION

The present invention relates to fabrication of semiconductor devices and, more particularly, to layer transfer techniques used in fabrication of semiconductor devices.

### BACKGROUND OF THE INVENTION

Microelectronic interconnects are critical for optimum performance, energy dissipation and signal integrity in semiconductor chips featuring gigascale integration (GSI). As the desired dimensions of interconnects shrink to allow for gigascale integration, signal delay and signal fidelity problems can significantly limit the overall system performance, e.g., maximum supportable chip clock frequencies. To address this problem, novel architectures based on three dimensional integration and three dimensional-device stacking are being investigated and implemented in current GSI designs.

The main benefits of three dimensional integration include a reduction in the length of the longest interconnects of the wiring distribution by a factor of 1/S^{1/2}, wherein S is the number of strata or layers in the three dimensional stack, and a corresponding increase in global clock frequency of S^{3/2}. See, for example, J. Joyner et al., A Three-dimensional Stochastic Wire Length Distribution for Variable Separation of Strata, PROCEEDINGS OF THE IEEE INTERNATIONAL INTERCONNECT TECHNOLOGY CONFERENCE, 132-34 (2000). Hence, three dimensional interconnect technologies provide higher interconnect densities and system speeds.

Layering technologies, achieved either by stacking a number of chips in one package or stacking a number of interconnect levels or devices on a chip, allow for enhanced design freedom. Additionally, stacking chips, layers or various devices fabricated with different materials and processes, allows for the incorporation of disparate technologies, such as radio frequency (RF) wireless interconnects and microphotonics, into silicon integrated circuits (IC)-based architectures.

The three dimensional integration and three dimensional-device structures have height-induced and performance-induced limitations placed on the number of layers that may be present. Heat removal and input/output interconnect demands of three dimensional-device structures also appear to be quite challenging. Hence, increased research efforts have been focused on improving methods to layer and reliably connect a large number of integrated circuits or devices for limited space applications.

Most of the processing proposed for three dimensional-device structures requires a carrier substrate (such as glass, silicon or ceramic), allowing for the transfer, placement and alignment of structural components. Taking into consideration the compatibility of silicon substrates with current IC-based technology and advances in silicon processing (for example, lithography, autohandling in high throughput cluster tooling used in reactive etching or deposition, deep via patterning, thinning and polishing), a silicon-based substrate is the carrier substrate of choice for fabricating the transferable structures, such as devices and interconnects

The carrier substrate and transferable structures, referred to hereafter as decals, are subsequently aligned and joined together with another IC silicon substrate to form the three dimensional architecture in GSI schemes. In order to successfully perform the transfer process, it is essential that the desired decal structure be released from the bulk of the carrier substrate, i.e., silicon-based carrier, in a facile manner, without damaging the intricate structures that are part of the decal structure.

The device transfer process typically requires a thinning step in which the thickness of the silicon-based carrier is decreased from about 0.7 millimeters to a significantly smaller design-specific value, typically in the range of about ten to about 100 micrometers. The final thickness of the silicon-based carrier depends on the number of decal layers envisioned in the three dimensional architecture. The final thickness of an individual decal has to be decreased as the number of decal layers increases for a given allowable total stack thickness. Usually grinding or etching methods are employed to accomplish this task. However, grinding and etching methods are very time consuming and potentially prone to damaging the structures present in the decal layers.

The most important problem however, is controlling the decal thickness across the substrate. The transfer of multiple active layers in integrated circuits using smart-cut methods is described, for example, in Yu, U.S. Pat. No. 6,320,228, “Multiple Active Layer Integrated Circuit and a Method of Making Such a Circuit.” The approach described therein is based on the use of a heavy dose hydrogen implantation and a thermal cycle to release the region of the wafer below the implant zone. The techniques are however limited to applications including a high temperature release process, i.e., wherein temperatures greater than 350 degrees celcius are allowed.

Additionally, thinning methods cause surface roughening. Surface roughening coupled with thickness non-uniformity requires that subsequent fine chemical-mechanical polishing (CMP) steps are needed. The use of CMP methods to thin the carrier is restricted to processes where only a few microns of the desired material are being removed, making it uneconomical when compared to the other aforementioned methods for the removal of substantial amount of silicon.

Another method to obtain a thin decal is based on incorporation of a layer of porous silicon created by an anodization process in the starting silicon carrier wafer and later used in subsequent process steps to release the undesired excess of silicon from the three-dimensional structure. The anodization process used to form the porous silicon layer is inexpensive and commonly used as a deposition method in IC technology.

Many commercial processes within porous-silicon based layer transfer have been realized by Canon, Inc. (Canon Kabushiki Kaisha) and have been utilized for several applications. In the first application, these processes have been applied to the fabrication of the silicon on insulator (SOI) substrates. See, for example, the description of Eltran® technology in Iwane et al., U.S. Pat. No. 6,140,209, “Process for Forming an SOI Substrate,” Sakaguchi et al., U.S. Pat. No. 6,350,702, “Fabrication Process of Semiconductor Substrate,” Sakaguchi et al., U.S. Pat. No. 6,121,112, “Fabrication Method for Semiconductor Substrate,” Yamagata et al., U.S. Pat. No. 5,679,475, “Semiconductor Substrate and Process for Preparing the Same,” Sakaguchi et al., U.S. Pat. No. 5,856,229, “Process for Production of Semiconductor Substrate,” Iwasaki et al., U.S. Pat. No. 6,258,698, “Process for Producing Semiconductor Substrate,” Sato et al., U.S. Pat. No. 6,309,945, “Process for Producing Semiconductor Substrate of SOI Structure.”In the second application, these processes have been applied to the fabrication of semiconductor devices, such as thin-film crystalline solar cells. See, for example, Nakagawa et al., U.S. Pat. No. 6,211,038, “Semiconductor Device, and Method for Manufacturing the Same,” Nishida et al., U.S. Pat. No. 6,331,208, “Process for Producing Solar Cell, Process for Producing Thin-Film Semiconductor, Process for Separating Thin-Film Semiconductor, and Process for Forming Semiconductor,” Nakagawa et al., U.S. Pat. No. 6,190,937, “Method of Producing Semiconductor Member and Method of Producing Solar Cell.”

In the third application, these processes have been applied to the fabrication of semiconductor article utilizing few layers of porous silicon. See, for example, Sakaguchi et al., U.S. Pat. No. 6,306,729, “Semiconductor Article and Method of Manufacturing the Same,” Sakaguchi et al., U.S. Pat. No. 6,100,165, “Method of Manufacturing Semiconductor Article.”After the layer transfer is completed and the release step, i.e., splitting, is implemented, porous coating remaining on the transferred layer needs to be removed. The removal can be accomplished by CMP, however surface non-uniformity, especially for large wafer-level substrates, is expected to be on the order of a few hundreds angstroms. Eltran® overcame the non-uniformity problem by employing an etching solution containing a mixture of buffered hydrofluoric acid (BHF), hydrogen peroxide (H₂O₂), and water (H₂O). However, after this wet cleaning step, the surface still needs to be annealed in hydrogen to smooth out the resulting micro-roughness of the surface.

Expanding on the Eltran technology, an improved method to create a semiconductor device layer using strained or unstrained silicon and germanium layers was presented in Chu et al., Pending U.S. application 2002/0096717 (hereinafter “Chu”). An important aspect of Chu was the need for the porous release layer to survive device-forming processing steps., i.e. to have sufficient thermal and mechanical stability to not release prematurely; or conversely, lose its releasing properties during high temperature activation anneals and CMP.

It would be desirable to have layer transfer techniques for producing decal structures and thus allowing creation of complex three dimensional integrated components. The techniques would allow for sufficient resistance to mechanical stresses encountered during the fabrication process, but enabling uniform release of structures to be transferred, the transfer itself performed in a facile manner, without damaging the intricate structures that it contains.

### SUMMARY OF THE INVENTION

The present invention provides techniques for the fabrication of semiconductor devices. In one aspect of the invention, a layer transfer structure is provided. The layer transfer structure comprises a carrier substrate having a porous region with a tuned porosity in combination with an implanted species, the position and amount of the implanted species defining a separation plane therein.

In another aspect of the invention, a method of forming a layer transfer structure comprises the following steps. A carrier substrate is provided. The carrier substrate is processed to create a porous region with a tuned porosity in combination with an implanted species, the position and amount of the implanted species defining a separation plane therein. A transferable decal layer may be fabricated, the decal layer comprising functional semiconductor components and interconnects.

The porous region may be exploited to allow for the creation of functional integrated circuits and packaging components, such as front end of the line (FEOL) and back end of the line (BEOL) structures, including, passivation layers, thin silicon interposers and heat sinks.

In yet another aspect of the invention, a method of forming a three dimensional integrated structure comprises the following steps. A decal structure comprising a transfer layer on a carrier substrate, the carrier substrate having a porous region with a tuned porosity and an implanted species defining a separation plane therein, is bonded to a receiver structure. The transfer layer is separated from the substrate at the separation plane in the porous region.

A more complete understanding of the present invention, as well as further features and advantages of the present invention, will be obtained by reference to the following detailed description and drawings.

### BRIEF DESCRIPTION OF THE DRAWINGS

FIGS. 1A-C are a collection of cross-section scanning electron micrograph (SEM) images of processes used to create a porous silicon region with graded porosity;

FIG. 2 is a diagram illustrating an exemplary technique for forming a silicon on insulator (SOI) substrate having a silicon substrate, a porous silicon layer and thermally regrown epitaxial layer;

FIG. 3 is an image of a substrate having a porous region with a tuned porosity wherein graded porosity is achieved by anodization of the silicon layer with a graded doping profile by ion implantation wherein the implanted species defines a separation plane therein according to an embodiment of the present invention;

FIG. 4 is a diagram illustrating an exemplary technique for forming a decal layer containing semiconducting components having a release layer according to an embodiment of the present invention; and

FIG. 5 is a diagram illustrating an exemplary technique for forming a decal layer containing semiconducting components having a release layer and a thermally regrown epitaxial layer according to an embodiment of the present invention.

### DETAILED DESCRIPTION OF PREFERRED EMBODIMENTS

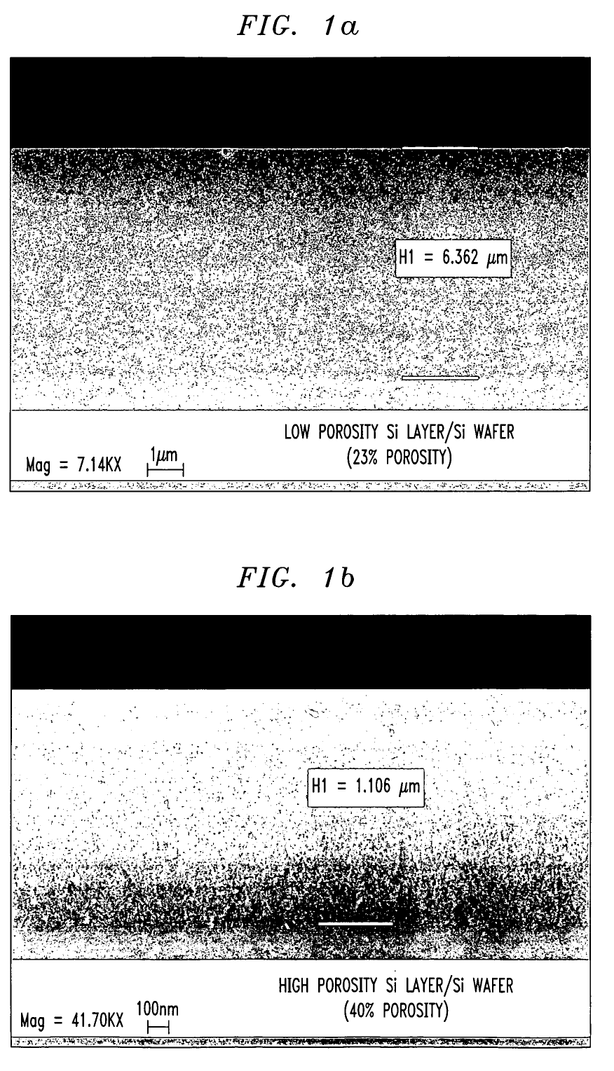

FIGS. 1A-C are a collection of cross-section scanning electron micrograph (SEM) images of processes used to create a porous silicon region with graded porosity. Tunable silicon porosity (pore size and density) may be realized by controlled variation of the anodization process. The most commonly utilized process leads to a bi-layer porous structure where the top of the porous structure is a layer created by forming a low porosity region, upon which the anodization conditions are changed so that deeper in the substrate a porous region of higher porosity level is created.

The examples of structures reproduced using a conventional technique are depicted in FIGS. 1A-C. More specifically, FIG. 1A shows an example of a porous silicon layer in which a lower level porosity is realized (about 23 percent of porosity). FIG. 1B, on the other hand, shows an example of the higher porosity silicon layer (about 40 percent of porosity) that can be achieved if the aforementioned anodization process is changed (voltage, ambient/solution or combination of both). In both cases, the depth of the porous layer can be controlled by the duration of the anodization process. Finally, FIG. 1C depicts a bi-layer consisting of silicon regions with both and high low levels of porosity, or graded porosity.

According to the techniques described herein, tunable porosity may also be achieved through the implantation of silicon having the appropriate ionic species, activating the ionic species by annealing and then anodizing the substrate to obtain the porous region. This method allows for a controlled way to achieve layer transfer by defining a separation plane in the porous region through implantation of a dopant and/or a non-dopant ion into the silicon-containing substrate.

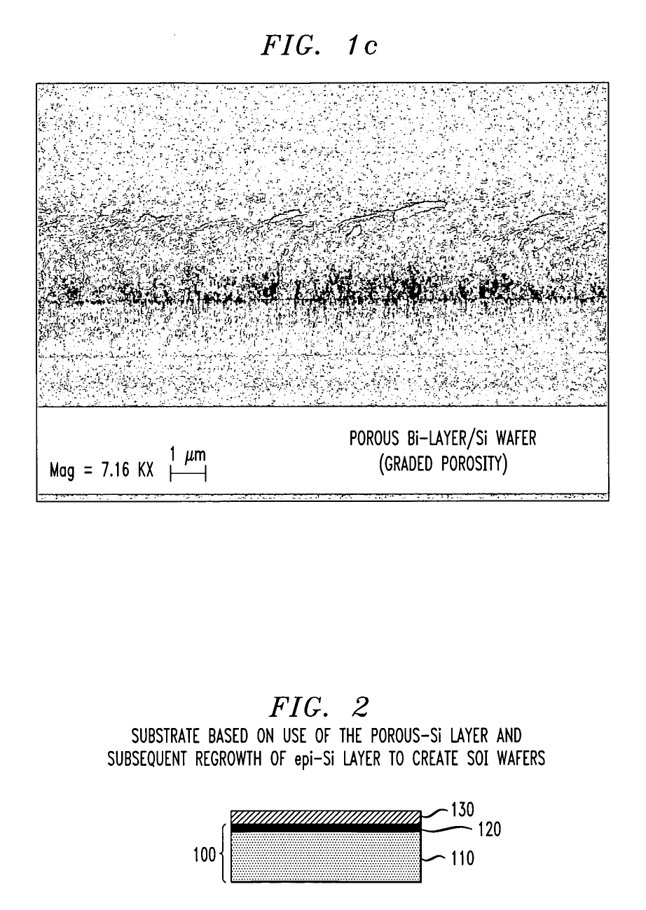

FIG. 2 is a diagram illustrating an exemplary technique for forming a silicon on insulator (SOI) substrate having a silicon substrate, a porous silicon layer and thermally regrown epitaxial layer. The creation of a thermally regrown epitaxial layer will be described in detail below.

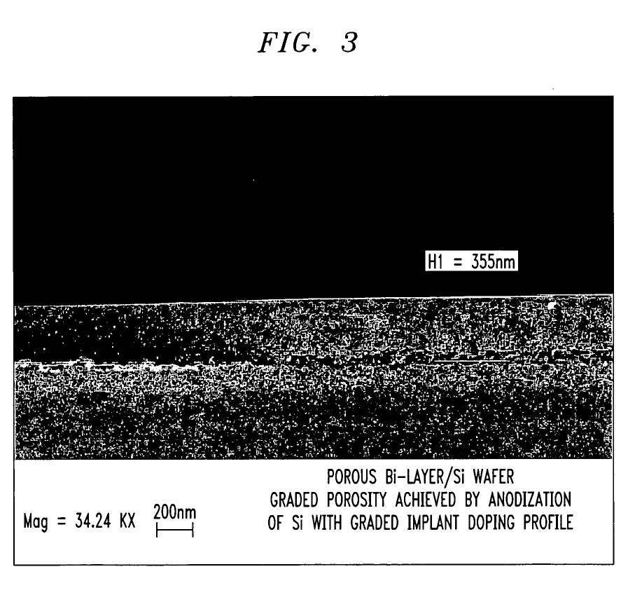

FIG. 3 is an scanning electron micrograph (SEM) cross section image of a substrate having an implanted species defining a separation plane therein. The image shown in FIG. 3 indicates how a silicon ion (Si+ ion) implant into a B+ implanted and annealed layer can create a high stress region after porous silicon formation. The discrete buried band within the porous silicon serves to initiate the separation.

As will be described below, for example in conjunction with the description present in the Example section, various substrates can be used to obtain the graded porosity layer using double-implantation layer techniques. Double-implantation layer techniques may comprise the following steps. A first implantation with boron is performed, followed by a second implantation with a group IVB species, such as silicon. The second implantation is targeted to implant a thinner region than the first implantation to create a sharp interface definition.

Activation of the boron implant by annealing is performed followed by anodization of the silicon to create the two regions of different porosity. An important aspect of the techniques provided herein is that to obtain various porosities, the anodization process does not have to be altered, i.e., the whole anodization process is performed at the same conditions (one anodization step). Another benefit is that well controlled tunability of the process is accomplished by varying the amount, i.e., dose and the position, i.e., depth of the implanted ions, providing needed stability of this bi-layer during further decal processing, but at the same time, enabling easy separation when release process is required. This well controlled tunability is essential to enable the structure to withstand the various processing steps required for the formation of the device, interconnect and packaging structures in the decal layer while it is still supported on the carrier substrate.

The conventional release layers technique or double implanted porous silicon layer technique as described herein, can be employed to create a decal allowing for the formation of a three dimensional integrated semiconductor structure, the double implanted porous silicon layer technique providing a more robust method to form the decals of interest.

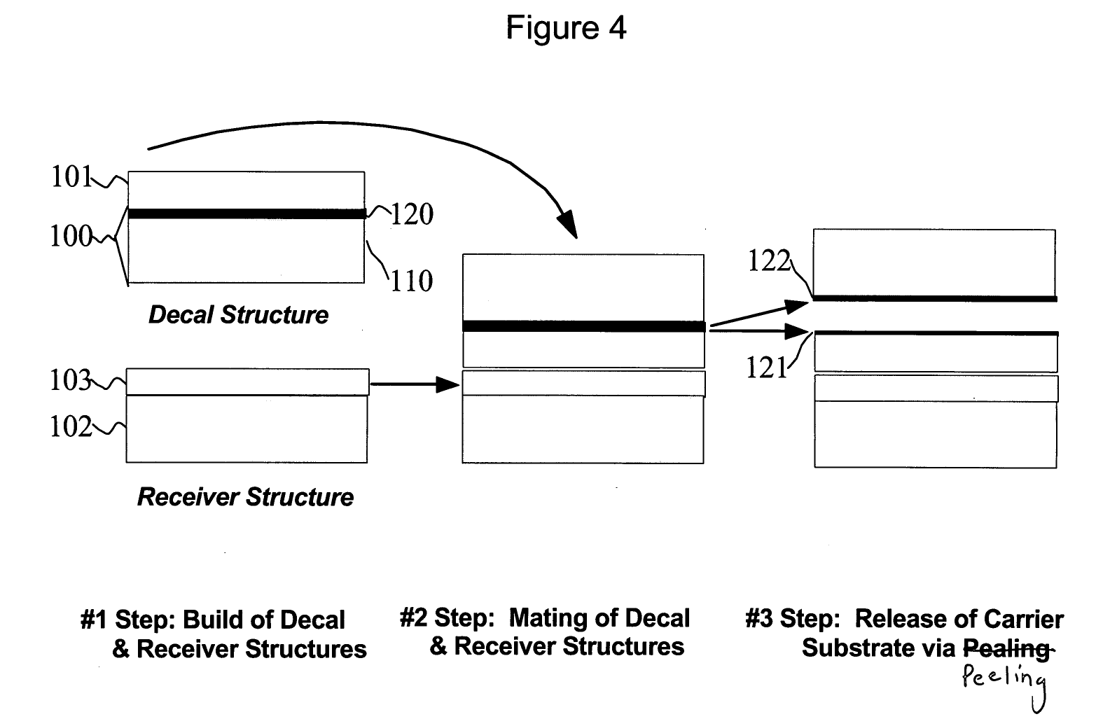

FIG. 4 is a diagram illustrating an exemplary technique for forming such a semiconductor decal. Specifically, in FIG. 4, the transfer of a layer, i.e., transfer layer 101, comprising semiconductor components is depicted, wherein carrier substrate 100, comprises a wafer-size substrate 110, a portion of which is anodized to form graded (variable porosity) porous region 120. Carrier substrate 100 may comprise any material suitable for further anodization to create a porous layer, including, but not limited to, silicon. Since a variety of specialized methods have been developed for silicon processing, the use of silicon is advantageous, as compared to other carrier technologies, as it provides a potential to create complete CMOS compatible systems with a low cost of ownership (COO).

For example, carrier substrate 100 may comprise a bi-layer porous region 120, having at least two different porosities, such as that achieved using conventional methods, or the tuned porosity structure achieved by the combination of the implantation and anodization techniques as described herein. Carrier substrate 100 may then be processed using complementary metal-oxide semiconductor (CMOS) technologies, or similar compatible technologies to form transfer layer 101. More specifically, transfer layer 101 may be formed by any suitable deposition methods, including, but not limited to, spin on coating, plasma enhanced deposition, physical vapor deposition, chemical vapor deposition, patterning methods and combinations comprising at least one of the foregoing deposition methods. A decal structure is thus fabricated. As will be described in detail below, the decal structure may comprise various components, including, but not limited to, functional semiconductor components and/or interconnects.

As depicted in FIG. 4, a receiver structure is created and processed at the same time as the decal structure is being fabricated. This parallel processing provides faster turn-around time and faster final design verification cycle when compared to other methods which use sequential builds. To create the receiver structure, semiconductor component layer 103 is built on top of base-substrate 102. Both the decal structure and the receiver structure formed should be CMOS compatible. Once the decal structure and the receiver structure have been created and processed, mating of the structures may be accomplished by alignment and bonding.

Bonding of the decal structure and the receiver structure can be performed by processes based on direct bonding, which comprises the fusion of various materials, including, but not limited to, oxides, nitrides, silicon and combinations comprising at least one of the foregoing materials. Bonding of the decal structure and the receiver structure can also be performed by processes based on indirect bonding, which comprises intermediate layers, including, but not limited to, metal-containing layers, polymer-containing layers, low-k material-based adhesive layers and combinations comprising at least one of the aforementioned layers.

The decal structure is then separated from the receiver structure, i.e., at carrier substrate 100. Carrier substrate 100 may have a separation plane defined therein, if the release layer was created using porous silicon bi-layer as in the conventional techniques or at the implant induced separation plane as disclosed herein. When the porous bi-layer is used, the bonded wafers split parallel to a surface proximate to the interface of layers having different porosities using splitting techniques. For example, a bi-layer porous region 120 may comprise two layers having different porosities, namely layer 121 and layer 122. In this case, splitting may occur proximate to the interface of layers 121 and 122. In the case of an implantation induced separation plane, splitting will again result in the separation of region 120 at the separation plane defined by implant location to form interface layers 121 and 122.

According to the techniques described herein, an increased functionality of the porous layer-based transfer process is accomplished by optimizing the properties of the porous layer. Namely, as described in conjunction with the descriptions of FIG. 1, FIG. 2 and FIG. 3, this porosity can be tuned to allow for mechanical stability of the structure during subsequent processing steps used in the fabrication of semiconductor components in transfer layer 101. An appropriate tailoring of the anodization process or double implantation is needed to create the optimum porous region 120, i.e., having a porous bi-layer with graded porosity, strong enough to withstand various CMOS-related processing steps, yet at the same time, weak enough to allow for easy separation of the decal from the carrier substrate. Semiconductor components fabricated in the transfer layer include, but are not limited to, semiconductor device elements, circuit elements, memory elements, thin-film layers, passive elements, active elements, interconnecting elements, micro-electro-mechanical elements, optical elements, optoelectronic elements, photonic elements and combinations comprising at least one of the foregoing components.

Additional benefits of using a porous silicon based carrier is that an epitaxial silicon layer is easily grown on the top of porous layer. This capability has been mainly utilized to create silicon on insulator (SOI) wafers. Using thermal treatments, the top layer of the porous structure seals, allowing for the creation of an epitaxial layer. It has been shown that very high quality epitaxial layers can be grown using this method, allowing for high performance applications. A conventional method for the formation of an epitaxial layer is depicted in FIG. 2, described above, enabling for a carrier substrate (having a silicon layer) to further comprise an epitaxial layer. More specifically, a porous region may be thermally treated to regrow the epitaxial layer to the desired thickness.

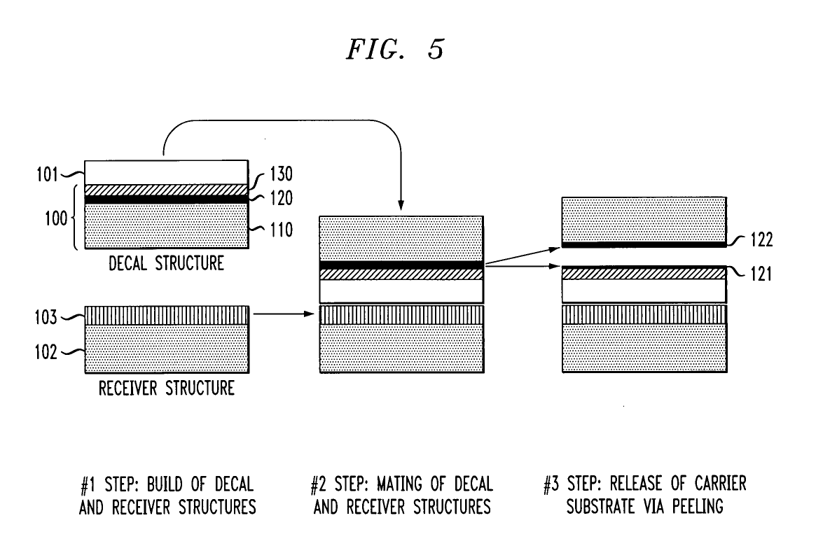

FIG. 5 is a diagram illustrating an exemplary technique for fabricating a decal comprising a thermally regrown epitaxial layer on the top of the porous region. The desired thickness of thermally regrown epitaxial layer 130 may be achieved by varying the thermal treatment (for example, time of the thermal treatment). Also, the quality of the regrown epitaxial layer (for example, defect density and resistivity) may be varied depending on the desired application (for example, by changing the ambient during the regrowth process). More specifically, in the conventional structure shown in FIG. 2, this epitaxial silicon layer is used to form device layer(s) to be transferred, while the implementations proposed in the present invention utilize the additional layer of semiconductor components, namely transfer layer 101, to provide additional functionality. This transfer layer may contain interconnecting structures, such as wires, and circuit signal modifying components, such as resistors, decoupling capacitors, repeaters, and if needed, packaging components. In the present approach, the thermally regrown epitaxial layer can be used to create a semiconductor device layer either before or after the fabrication of the decal, or either before or after the completion of the transfer process (including separation).

If transfer layer 101 comprises an interconnecting structure layer, then, after the transfer of the decal, it can be utilized to connect the semiconductor devices formed in thermally regrown epitaxial layer 130 to the device layers present in semiconductor component layer 103 of the receiver structure. Semiconductor device components that may be formed in thermally regrown epitaxial layer 130 include, but are not limited to, device layers, interposer structures, functional layers and combinations comprising at least one of the foregoing semiconductor components. The resulting device-interconnect-device composite represents a simple three dimensional integrated circuit structure. With the appropriate design (short wiring layout), the device-interconnect-device composite provides a fast path connection between various devices, e.g., between different layers, creating a structure suitable for high performance CMOS applications.

However, the thermally regrown epitaxial layer 130 is suitable for use in a variety of applications, including, but not limited to, the creation of new device layers for high performance CMOS technology. The techniques provided herein enable the formation of an interposer structure from thermally regrown epitaxial layer 130. Such an option is especially attractive for applications requiring new packaging interfaces with optimized input/output density and the provision of additional functionality, such as decoupling capacitors and resistors, provision of memory and mixed signal device stacking. Tailoring the thickness of thermally regrown epitaxial layer 130 enables the creation of an interposer structure that will provide mechanical support and heat spreading function in the final structure, such as for radio frequency (RF) components with a graded resistivity. The added functionalities of such approach include, but are not limited to, a specialized packaging interface (with optimized input/output connection density), added decoupling by incorporation of passive components (e.g., decoupling capacitors and resistors), a custom made fixture to allow for chips to connect to optoelectronic, photonics, microelectromechanical (MEM) or memory components and combinations comprising at least one or more of the foregoing functionalities.

The layer transfer process may be repeated multiple times, as desired. Repeating the transfer process multiple times can be used to create multi-layer three dimensional integrated structures.

To obtain smooth surfaces after the layer transfer, an optional blanket barrier layer, or capping coating, can be added on top of either porous region 120, or on the top of thermally regrown epitaxial layer 130, as part of the layer transfer process. The capping coating may be a blank film that serves as a hard mask or functions as a CMP stop or as an etch stop. The capping coating exhibits a high selectivity in removal rates as compared to other materials, such as porous silicon. Therefore, upon completion of the splitting process, porous region 120 can be uniformly processed using CMP to stop on the capping layer, resulting in a minimal long-range and short-range topography.

The material for the capping coating may be selected from well known CMOS dielectric barrier candidates, including, but not limited to, silicon oxide, silicon nitride, silicon carbide, amorphous films comprising silicon, carbon, oxygen, hydrogen, or combinations thereof. The capping coating may be deposited using any suitable deposition techniques, including, but not limited to, spin on coating, plasma enhanced deposition, physical vapor deposition, chemical vapor deposition, patterning methods and combinations comprising at least one of the foregoing deposition techniques.

The added capping coating, after the full layer transfer, can also serve other purposes. For example, once removal of porous region 120 is completed, appropriate terminal vias and contacts may be fabricated thereon, and through the capping coating using standard CMOS processing steps. Thus, a low cost of ownership scheme is provided wherein the added blanket barrier layer is not just a sacrificial layer in the removal process, but also aids in subsequent processing steps.

The capping coating may also comprise a thermally and/or electrically conducting layer, such as a metal-containing conducting layer or diamond like carbon layers, added on top of the underlying porous region 120. The conducting layer, comprising a blank film, may serve as a hard mask and as a ground shield layer that is connected to selected devices, or lines, in transfer layer 101 by insulated vias. Furthermore, the conducting layer can provide a heat spreading function in the final structure which would be particularly beneficial when three dimensional stacking of devices is performed using this process.

In commercial processes, porous silicon based technology is typically centered on the use of p-type silicon substrates, which brings about the issue of boron contamination. This issue becomes more critical when extended periods of high temperature cycles are part of the processing scheme. The capping coating can also be suitably selected to act as a diffusion barrier, protecting the to-be-transferred transfer layer 101 from potential degradation, yet at the same time, provide good adhesion to transfer layer 101.

If porous region 120 is tailored in such a way as to retain a thick region after splitting, such thick region may serve as a heat sink if the pores of such region are filled with a heat-conducting material. This process is achieved by creating a bi-layer porous region 120 consisting of one porous layer having a lower porosity, i.e., layer 121, closer to the surface of carrier substrate 100, and another porous layer with a much higher porosity, i.e., layer 122, underneath it. The two porous layers, layers 121 and 122, may each have a controlled thickness, that may be the same, or different, from each other.

If porous region 120 contains hydrogen, for example, if porous region 120 is implanted with hydrogen, or if a hydrogen-containing gas mixture is added (especially if a high concentration on the order of 1×10¹⁶ hydrogen ions per square centimeter (H⁺/cm²) is used) to porous region 120, thermal treatments, i.e., thermal activation, has the effect of inducing a growth of microcavities in porous region 120, resulting in the formation of micro-splittings or microcracks. Such a process enables easier separation of the layers, especially when lower temperature cycles are employed, using a variety of splitting techniques. Suitable splitting techniques include, but are not limited to, ultrasonic waves, thermal stress (heating or freezing), oxidation from the edge, insertion of solid wedge, insertion of fluid wedge using water jets and combinations comprising at least one of the foregoing splitting techniques.

With such a bi-layer porous region 120, splitting occurs parallel to the interface of these two porous layers due to the lattice mismatch and induced stresses present. After splitting, the higher porosity layer, layer 122, remains on the receiver structure. Layer 122 can be dipped in BHF to remove surface oxides and filled with a CMOS compatible thermally conducting material such as copper, diamond-like-carbon and the like to form an effective heat sink and heat spreader layer. Forming such a heat sink layer can be very beneficial especially if such a layer is sandwiched between high performance devices. Such a layer would provide fast and efficient cooling to locally heated areas.

The techniques described herein may be used to transfer a variety of semiconducting components. For example, both the decal and the receiver structures can include active, passive, interconnecting and other functional components related to microelectronics, optoelectronics, photonics, as well as micro-mechanical systems.

Semiconductor component layer 103, while on the decal structure, can contain packaging components, such as an interposer layer, as described above. Semiconductor component layer 103 may also contain non-CMOS-based elements that, when combined with the receiver CMOS-based structure, can result in the creation of mixed-technology systems. These mixed technology systems allow for the integration of heterogenous materials, devices and signals, and for flexibility in the device structures, system design and routing. For example, stacks of memory and logic components can be achieved, and/or digital, analog and RF circuits can be placed on different layers.

Since thermally regrown epitaxial layer 130 can be formed with a specific resistivity using doping (i.e., with dopants containing ambient during regrowth process) or ion implantation, thermally regrown epitaxial layer 130 may further be used for specialized applications, such as for the creation of particular device-type layers. For example, allowing for the formation of nMOS and pMOS devices on different layers, enabling greatly improved performance for each type through the choice of appropriate contact materials for example.

Graded resistivity would also enable the creation of an interposer for RF components. Even if the original carrier substrate 100 comprised a highly p-type doped wafer (which is needed to create a porous bi-layer), the final boron concentration may be tuned by growing a thicker thermally regrown epitaxial layer 130, as boron migration is a diffusion limited process.

A choice must be made between the particular processes employed to create the bi-layer porous region 120, the attachment process used to mate the decal structure with the receiver structure and other subsequent processes involved in creation of the decal structure. The attachment process used to mate the decal structure with the receiver structure is usually performed by bonding the structures. Since bonding strength dictates the mechanical stability of the structure, the adhesion strength between the porous layers needs to be lower than the bonding strength that allows for reliable processing (including a peeling step, as described above). The porosity and mechanical properties of bi-layer porous region 120 need to be tuned according to the specific application. For example, a final tuning of the porosity of porous region 120 may occur during anodization of the substrate.

For example, if semiconductor component layer 103 is fabricated and bonded using low temperature processes (most of the CMOS compatible processes need to be performed at temperatures lower then 450 degrees celcius (°C.)) the resulting thermal cycling will not be high enough to alter the porosity of the as-anodized silicon in porous region 120. However, if the bonding techniques or other processing steps employed involve extended periods of higher temperature treatments, initially higher porosity structures may be needed to counteract any sintering and closure of the pores to enable release of the decal. Also, this structure may not be applicable for processes involving high pressure, high stress, steps, as the bi-layer interface may prematurely release due to the thermomechanical stress of the joining step, resulting in low transfer yield.

The techniques described herein may be applied to optoelectronic device structures. In such applications however, the types of materials used to form layers, i.e., transfer layer 101, may be replaced with other materials, including materials comprising other semiconductors, such as gallium arsenide or indium phosphide, and those comprising organic materials. The materials should be selected according to the specific application. Carrier substrate 100 may serve as an integral part of optoelectronic structures, including three dimensional circuit stacks, allowing for integration of complex multifunctional and mixed-technology systems or elements on a single wafer.

The techniques herein provide an effective supporting structure for an integrated three dimensional IC for high frequency and high speed computing applications. Porous-silicon-based transfer technology may be utilized to form a complete, high density interconnect structure with integrated functional components. This low cost of ownership scheme may be used to create three dimensional integrated structures with functional components using low-temperature stress free porous silicon-based wafer-level layer transfer processes.

Although illustrative embodiments of the present invention have been described herein, it is to be understood that the invention is not limited to those precise embodiments, and that various other changes and modifications may be made by one skilled in the art without departing from the scope or spirit of the invention. The following example is provided to illustrate the scope and spirit of the present invention. Because this example is given for illustrative purposes only, the invention embodied therein should not be limited thereto.

### EXAMPLE

Method to create a separation layer using a combination of ion implantation and anodization:

Implantation of a Species into a Silicon Substrate:

Starting carrier substrate: boron-doped (about 1×10¹⁹ cm-3) silicon or substrate boron-doped (about 1×10¹⁹ cm-3) silicon with about two micrometers of undoped epitaxial silicon.

Process Steps:

1. Implantation: boron, 160 to 220 kiloelectron volt (keV), 1-5×10¹⁶ cm-2, +silicon, 200 to 400 keV, 1×10¹⁵ to 1×10¹⁶ cm-2, preferred→160 keV B+, 2×10¹⁶ cm-2+silicon, 220 keV, 2×10¹⁵ cm-2.

2. Boron electrical activation anneal: 550 to 800° C./15 minutes to 3 hours in a furnace or rapid thermal anneal (RTA) at 800 to 1100° C./5 to 500 seconds, preferred→650/165 minutes in a furnace.

3. Anodization: with the Substrate as the positive electrode and a platinum plate as a negative electrode, current densities (0.05 to 50 milli Amps (mA) cm-2).

This process leads to a typical porous structure with an implant induced separation plane as shown in FIG. 3.

1. A layer transfer structure comprising a carrier substrate having a porous region with a tuned porosity in combination with an implanted species defining a separation plane therein.

2. The structure of claim 1, wherein the separation plane is defined by a position and an amount of the implanted species.

3. The structure of claim 1, further comprising a transfer layer on the carrier substrate.

4. The structure of claim 1, further comprising a tunable thermally regrown epitaxial layer.

5. The structure of claim 4, wherein a component selected from the group consisting of a device layer, an interposer structure, a functional layer and combinations comprising at least one of the foregoing components is formed in the tunable thermally regrown epitaxial layer.

6. The structure of claim 1, wherein the porous region comprises a varied porosity.

7. The structure of claim 1, wherein the porous region comprises at least two different porosities.

8. The structure of claim 1, wherein the implanted species are selected from the group consisting of dopants, non-dopant ions and combinations comprising at least one of the foregoing species.

9. The structure of claim 1, wherein the implanted species comprise silicon ions.

10. The structure of claim 1, wherein the carrier substrate comprises silicon.

11. The structure of claim 3, wherein the transfer layer is formed by a process selected from the group consisting of spin on coating, plasma enhanced deposition, physical vapor deposition, chemical vapor deposition, patterning methods and combinations comprising at least one of the foregoing process.

12. A method of forming a layer transfer structure, the method comprising the steps of:
providing a carrier substrate; and
processing the carrier substrate to create a porous region with a tuned porosity in combination with an implanted species defining a separation plane therein.

13. The method of claim 12, wherein the separation plane is defined by a position and an amount of the implanted species.

14. The method of claim 12, wherein the processing step further comprises the step of anodizing areas of the porous region comprising the implanted species to create the separation plane.

15. The method of claim 12, wherein the processing step further comprises the steps of:
implanting a first species comprising boron; and
implanting a second different species.

16. The method of claim 12, wherein the porous region is thermally treated to form a regrown epitaxial layer.

17. The method of claim 12, wherein the porous region is implanted with a gas comprising hydrogen gas.

18. The method of 12, wherein the processing step further comprises the step of finally tuning the porosity of the porous region by anodization of the carrier substrate.

19. The method of claim 16, wherein the formation of the regrown epitaxial layer comprises tuning the thickness of the regrown epitaxial layer.

20. The method of claim 16, wherein the regrown epitaxial layer is processed to form a device layer having a specific resistivity using dopants containing ambient during the regrowth process.

21. The method of claim 16, wherein the regrown epitaxial layer is processed to form a device layer having a specific resistivity by ion implantation.

22. The method of claim 16, wherein the regrown epitaxial layer is used in the creation of NMOS devices on different layers.

23. The method of claim 16, wherein the regrown epitaxial layer is used in the creation of pMOS devices on different layers.

24. The method of claim 16, wherein the regrown epitaxial layer is processed to form an interposer structure with a specific resistivity using dopants containing ambient during the regrowth process.

25. The method of claim 16, wherein the regrown epitaxial layer is processed to form an interposer structure with a specific resistance by ion implantation.

26. The method of claim 16, wherein the regrown epitaxial layer is used for specialized applications selected from the group consisting of creation of interposer for radio frequency components with graded resistivity, creation of a new packaging interface with optimized input and output density, provision of additional functionality, provision of memory device stacking, provision of mixed signal device stacking, formation of a custom made fixture, and combinations comprising at least one of the foregoing specialized applications.

27. The method of claim 12, wherein the processing step further comprises the step of fabricating a transferable decal layer on the carrier substrate.

28. The method of claim 27, wherein the decal layer comprises functional semiconductor components and interconnects.

29. The method of claim 27, wherein the porous region is thermally treated to form a regrown epitaxial layer, the regrown epitaxial layer being processed to form a device layer before the decal layer is created.

30. The method of claim 27, wherein the porous region is thermally treated to form a regrown epitaxial layer, the regrown epitaxial layer adding functionality to the decal layer.

31. A method of forming a three dimensional integrated structure, the method comprising the steps of:
bonding a decal structure comprising a transfer layer on a carrier substrate, the substrate having a porous region with a tuned porosity in combination with an implanted species defining a separation plane therein, to a receiver structure; and
separating the transfer layer from the substrate at the separation plane in the porous region.

32. The method of claim 31, wherein the receiver structure comprises a base-substrate and a component layer.

33. The method of claim 31, wherein the component layer comprises a semiconductor component.

34. The method of claim 31, wherein the component layer comprises a semiconductor component selected from the group consisting of semiconductor device elements, circuit elements, memory elements, thin-film layers, passive elements, active elements, interconnecting elements, micro-electro-mechanical elements, optical elements, optoelectronic elements, photonic elements and combinations comprising at least one of the foregoing components.

35. The method of claim 31, wherein the porous region is thermally treated to form a regrown epitaxial layer.

36. The method of claim 35, wherein the regrown epitaxial layer is processed to form a device layer after separation is performed.

37. The method of claim 35, wherein the regrown epitaxial layer is processed to form an interposer structure providing mechanical support and heat spreading function.

38. The method of claim 31, wherein the steps of bonding and separating are repeated multiple times to create a multi-layer three-dimensional integrated structure.

39. The method of claim 31, wherein separation of the transfer layer from the substrate is initiated at the separation plane.

40. The method of claim 31, wherein separation of the transfer layer from the substrate comprises incorporation of a capping coating.

41. The method of claim 40, wherein the capping coating comprises a material selected from the group consisting of silicon oxide, silicon nitride, silicon carbide, amorphous films and combinations comprising at least one of the foregoing compounds.

42. The method of claim 40, wherein the capping coating comprises interconnects therein.

43. The method of claim 40, wherein the capping coating acts as a hardmask.

44. The method of claim 31, wherein a portion of the porous region remains on the transfer layer after separation.

45. The method of claim 44, wherein the portion of the porous region remaining on the transfer layer after separation is processed to form a heat sink by metalization.

46. The method of claim 31, wherein bonding the decal structure to the receiver structure comprises direct bonding of materials selected from the group consisting of oxides, nitrides, silicon and combinations comprising at least one of the foregoing materials.

47. The method of claim 31, wherein bonding the decal structure to the receiver structure comprises indirect bonding of an intermediate layer selected from the group consisting of metal-containing layers, polymer-containing layers, low-k material-based adhesive layers and combinations comprising at least one of the foregoing layers.

48. The method of claim 31, wherein the transfer layer is separated from the substrate using a splitting technique selected from the group consisting of ultrasonic waves, thermal stress induced by heating or cooling, oxidation from the edge, insertion of a solid wedge, insertion of a fluid wedge and combinations comprising at least one of the foregoing splitting techniques.
